(19) United States
(12) Patent Application Publication
(10) Pub. No.: US 2025/0237696 A1
(43) Pub. Date: Jul. 24, 2025

(54) PROBE SYSTEM, METHOD OF UTILIZING PROBE SYSTEM, METHOD OF TESTING UNPACKAGED SEMICONDUCTOR DEVICE, METHOD OF PRODUCING TESTED SEMICONDUCTOR DEVICE AND TESTED SEMICONDUCTOR DEVICE

(71) Applicant: MPI CORPORATION, Zhubei City (TW)

(72) Inventors: STOJAN KANEV, Zhubei City (TW); YU-HSUN HSU, Zhubei City (TW)

(21) Appl. No.: 19/019,973

(22) Filed: Jan. 14, 2025

Related U.S. Application Data
(60) Provisional application No. 63/637,883, filed on Apr. 24, 2024.
(60) Provisional application No. 63/624,136, filed on Jan. 23, 2024.

(51) Int. Cl. G01R 31/28; G01R 1/067

(52) U.S. Cl. CPC G01R 31/2875; G01R 1/06772; G01R 31/2889

(57) ABSTRACT

A probe system, a method of utilizing a probe system, a method of testing an unpackaged semiconductor device, a method of producing tested semiconductor device and a tested semiconductor device are provided. The probe system includes a platen, a temperature-controlled chuck, a testing assembly and a thermal actively-controlled mechanism. The temperature-controlled chuck supports a substrate that includes a device under test (DUT), and the temperature-controlled chuck regulates a temperature of the substrate. The testing assembly disposed on the platen. The testing assembly includes a waveguide interface instrument and a waveguide probe. The waveguide probe includes a probe tip configured to contact the DUT. The thermal actively-controlled mechanism is configured for stabilizing a thermal condition of the waveguide probe and blocking heat conduction from the temperature-controlled chuck to the waveguide probe.

### CROSS-REFERENCE TO RELATED PATENT APPLICATION

This application claims the benefit of priority to the U.S. Provisional Patent Application Ser. No. 63/624,136, filed on Jan. 23, 2024, which application is incorporated herein by reference in its entirety.

This application claims the benefit of priority to the U.S. Provisional Patent Application Ser. No. 63/637,883, filed on Apr. 24, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a system, methods and devices, and more particularly to a probe system, a method of utilizing a probe system, a method of testing an unpackaged semiconductor device, a method of producing a tested semiconductor device and a tested semiconductor device.

### BACKGROUND OF THE DISCLOSURE

Probe systems may be utilized to test the operation of an electronic component (e.g., a device under test, (DUT)), such as a semiconductor device and/or an integrated circuit device. The operational reliability of the electronic components is tested in probe system preferably under the environmental conditions that correspond to the conditions of use of the component in question. In this case, setting the test substrate to defined temperatures is a primary focus. The temperature of the test substrate is set by way of the chuck that can be heated or cooled by means of suitable devices.

For millimeter wave (mmW) and Terahertz (THz) tests, which generally are performed at frequencies between 50 gigahertz (GHz) and 2 terahertz (THz), signal path distances generally must be accounted for, and shorter signal paths generally produce more accurate test results. Additionally, during testing, the test probes, which are typically in the form of contacting needles, make contact with the electronic component to which test signals are applied or from which test signals are picked up. However, the temperature variations at the chuck can affect the temperature at the probe end. These temperature changes can significantly affect the test signals, particularly those at specific frequency, which are highly sensitive to temperature fluctuations.

Furthermore, when the probe tip, which is typically at a different temperature, makes contact with the electronic component that is heated by the chuck, heat transfer occurs between the probe tip and the electronic component. This heat transfer may affect electrical characteristics of a testing component (e.g., a waveguide) connected to the probe tip, leading to variations in the test signals.

Therefore, there exists a need for improved probe systems and methods. Isolating and stabilizing thermal radiation, thermal convection and thermal conduction for the test probes has become one of important issues in the art.

### SUMMARY OF THE DISCLOSURE

In response to the above-referenced technical inadequacies, the present disclosure provides a probe system, a method of utilizing a probe system, a method of testing an unpackaged semiconductor device, a method of producing a tested semiconductor device and a tested semiconductor device.

In order to solve the above-mentioned problems, one of the technical aspects adopted by the present disclosure is to provide a probe system, including a platen, a temperature-controlled chuck, a testing assembly and a thermal actively-controlled mechanism. The platen defines a platen aperture. The temperature-controlled chuck defines a support surface configured to support a substrate that includes a device under test (DUT), and the temperature-controlled chuck is configured to regulate a temperature of the substrate. The testing assembly is optionally and detachably disposed on the platen via a probe mount. The testing assembly includes a waveguide interface instrument and a waveguide probe. The waveguide interface instrument is operatively attached to the probe mount. The waveguide probe is operatively attached to the probe mount via the waveguide interface instrument, the waveguide probe includes a probe tip configured to contact the DUT, and at least a portion of the waveguide probe extends through the platen aperture to facilitate contact between the probe tip and the DUT. The thermal actively-controlled mechanism is configured for stabilizing a thermal condition of the waveguide probe and blocking heat conduction from the temperature-controlled chuck to the waveguide probe.

In order to solve the above-mentioned problems, another one of the technical aspects adopted by the present disclosure is to provide a method of utilizing a probe system, and the method includes: (i) testing one or more devices under test (DUTs) by the testing assembly of the probe system; and (ii) concurrently with the testing of the one or more DUTs, stabilizing the thermal condition of the waveguide probe and blocking the heat conduction from the temperature-controlled chuck to the waveguide probe. The process of stabilizing the thermal condition and blocking the heat conduction includes: (a) employing the thermal actively-controlled mechanism that includes a waveguide enclosure defining an enclosed space, and circulating a temperature-controlled fluid through the enclosed space to stabilize the thermal condition of the waveguide probe; and (b) utilizing a fluid circulating module connected to an inlet and an outlet of the waveguide enclosure, wherein the fluid circulating module continuously inputs the temperature-controlled fluid into the enclosed space through the inlet and continuously removes fluid through the outlet, thereby blocking the heat conduction from the temperature-controlled chuck to the waveguide probe.

In order to solve the above-mentioned problems, another one of the technical aspects adopted by the present disclosure is to provide a method of testing an unpackaged semiconductor device being formed on a substrate, and the method includes: providing the probe system mentioned above; electrically connecting the testing assembly with the unpackaged semiconductor device by making the probe tip of the testing assembly in contact with the contact of the unpackaged semiconductor device; and testing the unpackaged semiconductor device by using the testing assembly to transmit a signal between the unpackaged semiconductor device and a tester.

In order to solve the above-mentioned problems, another one of the technical aspects adopted by the present disclosure is to provide a method of producing a tested semiconductor device, and the method includes: providing the probe system mentioned above; providing an unpackaged semiconductor device, wherein the unpackaged semiconductor device is formed on a substrate and includes at least one contact; electrically connecting the testing assembly to the unpackaged semiconductor device by making the probe tip of the testing assembly in contact with the contact of the unpackaged semiconductor device; and testing the unpackaged semiconductor device by using the testing assembly to transmit a signal between the unpackaged semiconductor device and a tester.

In order to solve the above-mentioned problems, another one of the technical aspects adopted by the present disclosure is to provide a tested semiconductor device, including an unpackaged semiconductor device having a plurality of contacts configured to be mechanically and electrically contacted by the probe system mentioned above after performing a testing process.

Therefore, in the probe system, the method of utilizing a probe system, the method of testing the unpackaged semiconductor device, the method of producing the tested semiconductor device and the tested semiconductor device provided by the present disclosure, when the probe tip makes contact with the DUT that is heated by the temperature-controlled chuck, the fluid circulating module can be used for stabilizing the thermal condition, so as to block the heat conduction from the temperature-controlled chuck to the waveguide probe, thereby reducing variations in the test signals.

Moreover, the thermal shielding component can be configured for restricting heat transferring between the testing assembly and the temperature-controlled chuck, shielding a first part of the testing assembly from the temperature-controlled chuck, shielding a second part of the testing assembly from the temperature-controlled chuck, and/or maintaining thermal gradients between the testing assembly and the temperature-controlled chuck when the testing assembly is optionally and detachably disposed above the temperature-controlled chuck.

In addition, the thermal vacuum component forms a vacuum layer significantly reduces heat transfer by conduction and convection between the temperature-controlled chuck and the testing assembly. The thermal reflecting component can be configured for restricting heat transferring between the testing assembly and the temperature-controlled chuck by reflecting thermal radiation away from the testing assembly, shielding at least a part of the testing assembly from thermal radiation emitted by the temperature-controlled chuck, and/or a thermal gradient between the testing assembly 44 and the temperature-controlled chuck by reflecting and managing thermal energy when the testing assembly is optionally and detachably disposed above the temperature-controlled chuck.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of a probe system according to a first embodiment of the present disclosure;

FIG. 2 is a schematic diagram of a probe system according to a second embodiment of the present disclosure;

FIG. 3 is a schematic diagram of a probe system according to a third embodiment of the present disclosure;

FIG. 4 is a schematic diagram of a probe system according to a fourth embodiment of the present disclosure;

FIG. 5 is a flowchart of a method of utilizing the probe system of the first, second, third and fourth embodiments according to one embodiment of the present disclosure; and

FIG. 6 is a detailed flowchart of step S11.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

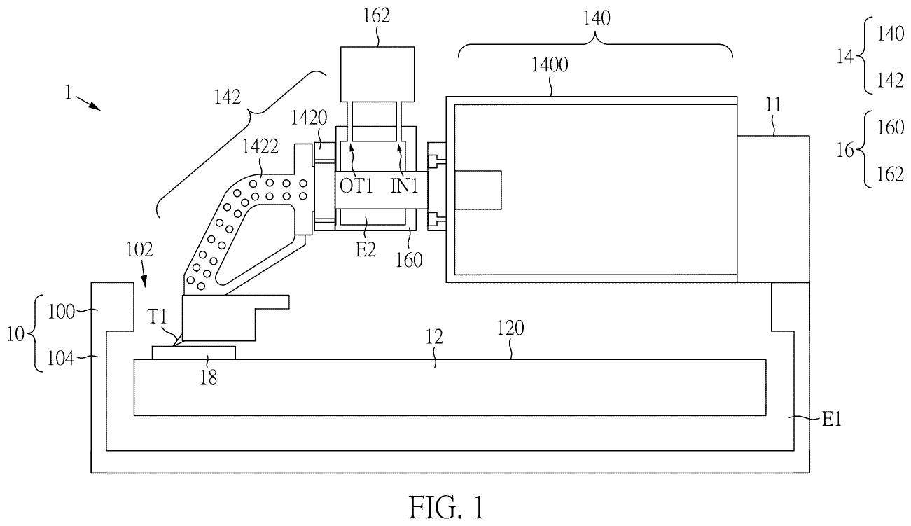

FIG. 1 is a schematic diagram of a probe system according to a first embodiment of the present disclosure. Referring to FIG. 1, a first embodiment of the present disclosure provides a probe system 1. The probe system 1 includes a platen 100, a temperature-controlled chuck 12, a testing assembly 14 and a thermal actively-controlled mechanism 16.

The platen 100 can be a part of a machine frame structure 10 and defines a platen aperture 102. The machine frame structure 10 has a lower enclosure 104 that at least partially defines and/or bound a space E1 for accommodating the temperature-controlled chuck 12. In other words, the lower enclosure 104 can surround, house, and/or contain at least a portion of the temperature-controlled chuck 12, such as a portion of the temperature-controlled chuck 12 that defines a support surface 120. Furthermore, the platen 100 can provide a platform at the top of the lower enclosure to support the testing assembly 14.

The temperature-controlled chuck 12 typically has a flat, smooth support surface 120 designed to provide uniform contact with the substrate 18 that includes a device under test (DUT) also referred to as an unpackaged semiconductor device. The support surface 120 is also used to support the substrate 18. The temperature-controlled chuck 120 can be equipped with heating and/or cooling elements that allow precise temperature regulation for the substrate 18. The temperature can range from very low (e.g., −190° C.) to very high (e.g., +600° C.) depending on the application. In certain embodiments, sensors and feedback mechanisms can be utilized to maintain the desired temperature with high accuracy and stability.

Although not shown in the drawings, a translation stage can be provided and configured to operatively translate the temperature-controlled chuck 12 along an X-axis, a Y-axis, and/or a Z-axis. Additionally or alternatively, the translation stage can be configured to rotate the temperature-controlled chuck 12 about the X-axis, the Y-axis, and/or the Z-axis.

The testing assembly 14 can be optionally and detachably disposed on the platen 10 via a probe mount 11. The testing assembly 14 includes a waveguide interface instrument 140 and a waveguide probe 142. The waveguide interface instrument 140 is operatively attached to the probe mount 11. The waveguide interface instrument 140 can include a frequency extender, which can also be referred to herein as, or can be, a vector network analyzer (VNA) extender, a spectrum analyzer extender, a waveguide tuner and/or a signal analyzer extender. For example, the waveguide interface instrument 140, such as a VNA extender, is configured to transmit and receive signals between the waveguide probe 142 of the testing assembly and a tester, such as a vector network analyzer (VNA), which is to evaluate the performance and characteristics of the device under test (DUT).

It should be understood that the VNA extender can include an electronic component, a spectrum analyzer extender, and/or a signal analyzer extender. The VNA extender, when present, can be operatively attached to a corresponding probe mount 11 of a corresponding manipulator (not shown in the drawings), and a corresponding probe may be operatively attached to the corresponding manipulator via the VNA extender. The VNA, as the tester, facilitates the testing by generating and receiving high-frequency signals to and from the DUT, enabling detailed measurements of the device's characteristics under test conditions.

The waveguide probe 142 is operatively attached to the probe mount 11 via the waveguide interface instrument 140, The waveguide probe 142 can face toward the support surface 120 of the temperature-controlled chuck 12 such that the waveguide probe 142 can contact, or electrically contact, the DUT. For example, the waveguide probe 142 has one or more contact components for contacting one or more contact locations on the DUT. This contact may be selectively established and/or disrupted via the motion of the temperature-controlled chuck 12, such as through an actuation of a translation stage, and/or via the motion of the waveguide probe 142, such as through the actuation of manipulators.

In the present embodiment, the waveguide probe 142 can include a probe tip T1 configured to contact the DUT, and a part of the waveguide probe 142 can extend through the platen aperture 102 to facilitate contact between the probe tip T1 and the DUT. Moreover, the waveguide probe 142 also includes a waveguide section 1420 and a waveguide channel section 1422, the waveguide section 1420 has a first end and a second end, the first end is operatively attached to the waveguide channel section 1422, and the second end is operatively attached to a frequency extender 1400 of the waveguide interface instrument 140.

The waveguide section 1420 and the waveguide channel section 1422 together form a structure that guides electromagnetic waves from the frequency extender 1400 to the DUT. The waveguide section 1420 and the waveguide channel section 1422 are carefully designed to ensure minimal signal loss and maintain the integrity of high-frequency test signals. For example, the waveguide section 1420 can be a rectangular waveguide, a circular waveguide, an elliptical waveguide or a ridged waveguide, and the waveguide channel section 1422 can be a waveguide block having a curved and slender structure capable of clamping the probe tip T1.

Furthermore, the thermal actively-controlled mechanism 16 can include a waveguide enclosure 160 configured for defining an enclosed space E2, and a portion of the waveguide probe 142 is disposed within the enclosed space E2. For example, the portion of the waveguide probe 142 is disposed within the enclosed space E2 can include the waveguide section 1420.

The thermal actively-controlled mechanism 16 is mainly used for stabilizing a thermal condition of the waveguide probe 142 and blocking heat conduction from the temperature-controlled chuck 12 to the waveguide probe 142.

In the present embodiment, the thermal actively-controlled mechanism 16 also includes a fluid circulating module 162 connected to an inlet IN1 and an outlet OT1 of the waveguide enclosure 160, and the fluid circulating module 162 can be used for stabilizing the thermal condition by continuously inputting a temperature-controlled fluid into the enclosed space E2 through the inlet IN1 and continuously removing fluid from the enclosed space E2 through the outlet OT1, so as to block the heat conduction from the temperature-controlled chuck 12 to the waveguide probe 142.

More specifically, the waveguide enclosure 160 can be provided with an active cooling/heating mechanism by using the fluid circulating module 162, also referred to as a forced heat convection mechanism. The fluid circulating module 162 can be a fluid supply or a fluid source for providing cooling fluid, which can be gas (e.g., compressed dry air (CDA)) or liquid (e.g., cooling water). The temperature of the cooling air can be adjusted according to a preset testing condition of the substrate 18. For example, the temperature of the cooling air of the waveguide enclosure 160 can be lower than 25° C.

In addition, a flow rate of the cooling air can be controlled by the fluid circulating module 162, for example, can be lower than 20 L/min, preferably between 5 to 10 L/min. In certain cases, a thermal sensor can be disposed within the waveguide enclosure 160 and electrically connected to the fluid circulating module 162 for feedback control, such that the temperature of the cooling air and the flow rate of the cooling air can be controlled precisely according to a temperature sensed by the thermal sensor.

Therefore, when the probe tip T1 makes contact with the DUT that is heated by the temperature-controlled chuck 12, the fluid circulating module 162 can be used for stabilizing the thermal condition, so as to block the heat conduction from the temperature-controlled chuck 12 to the waveguide probe 142, thereby reducing variations in the test signals.

### Second Embodiment

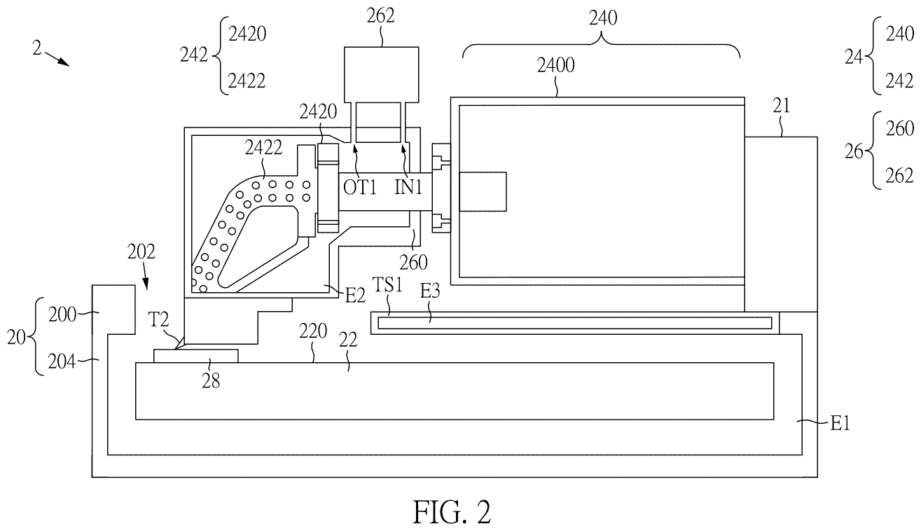

FIG. 2 is a schematic diagram of a probe system according to a second embodiment of the present disclosure. Referring to FIG. 2, a second embodiment of the present disclosure provides a probe system 2. The probe system 2 includes a platen 200, a temperature-controlled chuck 22, a testing assembly 24 and a thermal actively-controlled mechanism 26.

The second embodiment differs from the first embodiment in that the platen 200 further includes a thermal shielding component TS1 disposed between the testing assembly 24 and the temperature-controlled chuck 22. The thermal shielding component TS1 has a heat insulating layer configured for blocking radiation heat from the temperature-controlled chuck 22 to the waveguide probe 242. More specifically, the thermal shielding component TS1 can be configured for blocking radiation heat from the temperature-controlled chuck 22 to the waveguide interface instrument 240. The heat insulating layer can be designed to form an enclosed space E3 therewithin, and CDA can be filled into the enclosed space E3.

The thermal shielding component TS1 can be configured for restricting heat transferring between the testing assembly and the temperature-controlled chuck. Moreover, the thermal shielding component TS1 can be configured for shielding at least a part of the testing assembly 24 from the temperature-controlled chuck 22. In addition, the thermal shielding component TS1 can be configured for maintaining thermal gradients between the testing assembly 24 and the temperature-controlled chuck 22 when the testing assembly 24 is optionally and detachably disposed above the temperature-controlled chuck 22.

The platen 200 can be a part of a machine frame structure 20 and defines a platen aperture 202. The machine frame structure 20 has a lower enclosure 204 that at least partially defines and/or bound a space E1 for accommodating the temperature-controlled chuck 22. In other words, the lower enclosure 204 can surround, house, and/or contain at least a portion of the temperature-controlled chuck 22, such as a portion of the temperature-controlled chuck 22 that defines a support surface 220. Furthermore, the platen 200 can provide a platform at the top of the lower enclosure to support the testing assembly 24.

The testing assembly 24 can be optionally and detachably disposed on the platen 200 via a probe mount 21. The testing assembly 24 includes a waveguide interface instrument 240 and a waveguide probe 242. The waveguide interface instrument 240 is operatively attached to the probe mount 21.

The waveguide probe 242 is operatively attached to the probe mount 21 via the waveguide interface instrument 240, The waveguide probe 242 can face toward the support surface 220 of the temperature-controlled chuck 22 such that the waveguide probe 242 can contact, or electrically contact, the DUT.

In the present embodiment, the waveguide probe 242 can include a probe tip T2 configured to contact the DUT, and a part of the waveguide probe 242 can extend through the platen aperture 202 to facilitate contact between the probe tip T2 and the DUT. Moreover, the waveguide probe 242 also includes a waveguide section 2420 and a waveguide channel section 2422.

Furthermore, the thermal actively-controlled mechanism 26 can include a waveguide enclosure 260 configured for defining an enclosed space E2, and a portion of the waveguide probe 242 is disposed within the enclosed space E2. Different from the first embodiment, the portion of the waveguide probe 242 is disposed within the enclosed space E2 can include the waveguide section 2420 and the waveguide channel section 2422.

In this case, the thermal actively-controlled mechanism 26 can used for stabilizing a thermal condition of the waveguide section 2420 and the waveguide channel section 2422 and blocking heat conduction from the temperature-controlled chuck 22 to the waveguide section 2420 and the waveguide channel section 2422.

Therefore, when the probe tip T2 makes contact with the DUT that is heated by the temperature-controlled chuck 22, the fluid circulating module 262 can be used for stabilizing the thermal condition, so as to block the heat conduction from the temperature-controlled chuck 22 to the waveguide probe 242, thereby reducing variations in the test signals.

Furthermore, in certain cases, the enclosed space E3 of the thermal shielding component TS1 can be connected to another fluid circulating module, and a temperature and a flow rate of the fluid inside the thermal shielding component TS1 can be controlled. For example, the temperature of the cooling air of the waveguide enclosure 260 can be lower than the temperature of the cooling air of the thermal shield component TS1, and the flow rate of the cooling air of the waveguide enclosure 260 can be lower than the flow rate of the cooling air of the thermal shield component TS1, but the present disclosure is not limited thereto.

### Third Embodiment

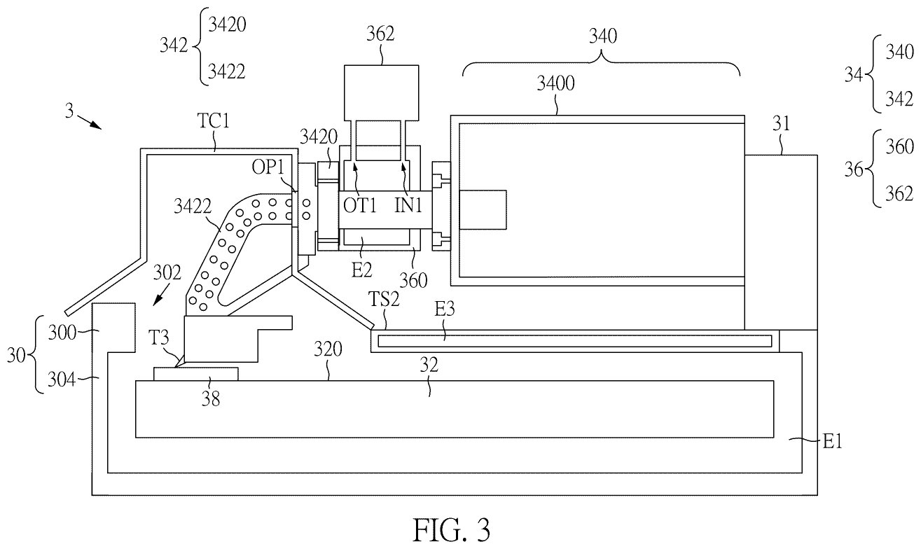

FIG. 3 is a schematic diagram of a probe system according to a third embodiment of the present disclosure. Referring to FIG. 3, a third embodiment of the present disclosure provides a probe system 3. The probe system 3 includes a platen 300, a temperature-controlled chuck 32, a testing assembly 34 and a thermal actively-controlled mechanism 36.

The third embodiment differs from the second embodiments in that the platen 300 further includes a thermal cover TC1 surrounding, housing and/or containing a portion of the waveguide probe 342. For example, a waveguide interface instrument 340 and/or a waveguide probe 342 can be surrounded, housed or contained by the thermal cover TC1. In FIG. 3, a part of a waveguide section 3420 and a part of a waveguide channel section 3422 of the waveguide probe 342 can be surrounded, housed or contained by the thermal cover TC1. Moreover, the thermal cover TC1 covers the platen aperture 302 and has an opening OP1 through which the testing assembly 34 penetrates. For example, the waveguide channel section 3422 can penetrate through the opening OP1, such that the probe tip T3 can make contact with the DUT.

In the present embodiment, the thermal shielding component TS2 disposed between the testing assembly 34 and the temperature-controlled chuck 32. The thermal shielding component TS2 has a heat insulating layer configured for blocking radiation heat from the temperature-controlled chuck 32 to the waveguide probe 342. The heat insulating layer can be designed to form an enclosed space E3 therewithin, and CDA can be filled into the enclosed space E3.

The thermal shielding component TS2 can be configured for restricting heat transferring between the testing assembly 34 and the temperature-controlled chuck 32. Moreover, the thermal shielding component TS1 can be configured for shielding a first part of the testing assembly 34 from the temperature-controlled chuck 32, and the thermal cover TC1 can be configured for shielding a second part of the testing assembly 34 from the temperature-controlled chuck 32. In addition, the thermal shielding component TS2 together with the thermal cover TC1 can be configured for maintaining thermal gradients between the testing assembly 34 and the temperature-controlled chuck 32 when the testing assembly 34 is optionally and detachably disposed above the temperature-controlled chuck 32.

The platen 300 can be a part of a machine frame structure 30 and defines a platen aperture 302. The machine frame structure 30 has a lower enclosure 304 that at least partially defines and/or bound a space E1 for accommodating the temperature-controlled chuck 32.

The testing assembly 34 can be optionally and detachably disposed on the platen 300 via a probe mount 31. The testing assembly 34 includes a waveguide interface instrument 340 and a waveguide probe 342. The waveguide interface instrument 340 is operatively attached to the probe mount 31.

The waveguide probe 342 is operatively attached to the probe mount 31 via the waveguide interface instrument 340, The waveguide probe 342 can face toward the support surface 320 of the temperature-controlled chuck 22 such that the waveguide probe 342 can contact, or electrically contact, the DUT.

In the present embodiment, the waveguide probe 342 can include a probe tip T2 configured to contact the DUT, and a part of the waveguide probe 342 can extend through the platen aperture 302 to facilitate contact between the probe tip T2 and the DUT.

Furthermore, the thermal actively-controlled mechanism 36 can include a waveguide enclosure 360 configured for defining an enclosed space E2, and a portion of the waveguide probe 342 is disposed within the enclosed space E2. The portion of the waveguide probe 342 disposed within the enclosed space E2 can include the waveguide section 3420.

In this case, the thermal actively-controlled mechanism 36 can used for stabilizing a thermal condition of the waveguide section 3420 and blocking heat conduction from the temperature-controlled chuck 32 to the waveguide section 3420.

Therefore, when the probe tip T3 makes contact with the DUT that is heated by the temperature-controlled chuck 32, the fluid circulating module 362 can be used for stabilizing the thermal condition, so as to block the heat conduction from the temperature-controlled chuck 32 to the waveguide probe 342, thereby reducing variations in the test signals.

Furthermore, in certain cases, the enclosed space E3 of the thermal shielding component TS2 can be connected to another fluid circulating module, and a temperature and a flow rate of the fluid inside the thermal shielding component TS2 can be controlled. For example, the temperature of the cooling air of the waveguide enclosure 360 can be lower than the temperature of the cooling air of the thermal shield component TS2, and the flow rate of the cooling air of the waveguide enclosure 360 can be lower than the flow rate of the cooling air of the thermal shield component TS2, but the present disclosure is not limited thereto.

### Fourth Embodiment

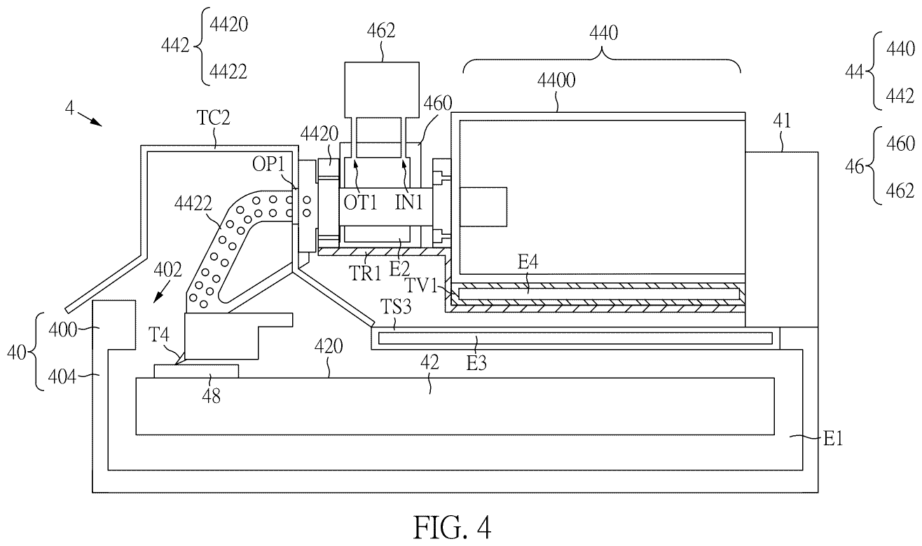

FIG. 4 is a schematic diagram of a probe system according to a fourth embodiment of the present disclosure. Referring to FIG. 4, a fourth embodiment of the present disclosure provides a probe system 4. The probe system 4 includes a platen 400, a temperature-controlled chuck 42, a testing assembly 44 a thermal actively-controlled mechanism 46.

The fourth embodiment differs from the above embodiments in that the probe system 4 further includes a thermal vacuum component TV1 and a thermal reflecting component TR1 that are disposed between the testing assembly 44 and the temperature-controlled chuck 42.

The thermal vacuum component TV1 is designed to minimize heat transfer between the temperature-controlled chuck 42 and the testing assembly 44, while maintaining the temperature of the testing assembly 44. The thermal vacuum component TV1 includes a plurality of walls, typically made of stainless steel, form a vacuum space E4 therebetween. The thermal vacuum component TV1 forms a vacuum layer significantly reduces heat transfer by conduction and convection between the temperature-controlled chuck 42 and the testing assembly 44.

The thermal reflecting component TR1 can be formed between the waveguide enclosure 460 and the temperature-controlled chuck 42, and can be coated on a surface of the thermal vacuum component TV1. The thermal reflecting component TR1 can be made by a reflective material, such as silver, such that the infrared radiation from the temperature-controlled chuck 42 can be reflected, further reducing heat transfer by radiation.

It should be noted that one or both of the thermal vacuum component TV1 and the thermal reflecting component TR1 can be utilized in the probe system 4. In a case that the thermal vacuum component TV1 is only utilized, the thermal vacuum component TV1 can be disposed on a surface of the waveguide enclosure 460 and a surface of the waveguide interface instrument 440 that face toward the temperature-controlled chuck 42. However, the aforementioned details are disclosed for exemplary purposes only, and are not meant to limit the scope of the present disclosure.

More specifically, the thermal reflecting component TR1 can be configured for restricting heat transferring between the testing assembly 44 and the temperature-controlled chuck 42 by reflecting thermal radiation away from the testing assembly 44. In addition, the thermal reflecting component TR1 can be configured for shielding at least a part of the testing assembly 44 (e.g., the waveguide probe section 442 and the waveguide interface instrument 440) from thermal radiation emitted by the temperature-controlled chuck 42. Moreover, the thermal reflecting component TR1 can be configured for maintaining a thermal gradient between the testing assembly 44 and the temperature-controlled chuck 42 by reflecting and managing thermal energy when the testing assembly 44 is optionally and detachably disposed above the temperature-controlled chuck 42.

In this embodiment, the platen 400 similarly includes a thermal cover TC3 surrounding, housing and/or containing a portion of the waveguide probe 442. In FIG. 4, a part of a waveguide section 4420 and a part of a waveguide channel section 4422 of the waveguide probe 442 can be surrounded, housed or contained by the thermal cover TC2.

Similarly, the thermal shielding component TS2 disposed between the testing assembly 44 and the temperature-controlled chuck 42. The thermal shielding component TS3 has a heat insulating layer configured for blocking radiation heat from the temperature-controlled chuck 42 to the waveguide probe 442. The heat insulating layer can be designed to form an enclosed space E3 therewithin, and CDA can be filled into the enclosed space E3.

The thermal shielding component TS3 can be configured for restricting heat transferring between the testing assembly 44 and the temperature-controlled chuck 42. Moreover, the thermal shielding component TS3 can be configured for shielding a first part of the testing assembly 44 from the temperature-controlled chuck 42, and the thermal cover TC2 can be configured for shielding a second part of the testing assembly 44 from the temperature-controlled chuck 42. In addition, the thermal shielding component TS3 together with the thermal cover TC1 can be configured for maintaining thermal gradients between the testing assembly 44 and the temperature-controlled chuck 42 when the testing assembly 44 is optionally and detachably disposed above the temperature-controlled chuck 42.

The platen 400 can be a part of a machine frame structure 40 and defines a platen aperture 402. The machine frame structure 40 has a lower enclosure 404 that at least partially defines and/or bound a space E1 for accommodating the temperature-controlled chuck 42.

The testing assembly 44 can be optionally and detachably disposed on the platen 400 via a probe mount 41. The testing assembly 34 includes a waveguide interface instrument 440 and a waveguide probe 442. The waveguide interface instrument 440 is operatively attached to the probe mount 41.

The waveguide probe 442 is operatively attached to the probe mount 41 via the waveguide interface instrument 440, The waveguide probe 442 can face toward the support surface 420 of the temperature-controlled chuck 42 such that the waveguide probe 442 can contact, or electrically contact, the DUT.

In the present embodiment, the waveguide probe 442 can include a probe tip T4 configured to contact the DUT, and a part of the waveguide probe 442 can extend through the platen aperture 402 to facilitate contact between the probe tip T4 and the DUT.

Furthermore, the thermal actively-controlled mechanism 46 can include a waveguide enclosure 460 configured for defining an enclosed space E2, and a portion of the waveguide probe 442 is disposed within the enclosed space E2. The portion of the waveguide probe 442 disposed within the enclosed space E2 can include the waveguide section 4420.

In this case, the thermal actively-controlled mechanism 46 can used for stabilizing a thermal condition of the waveguide section 4420 and blocking heat conduction from the temperature-controlled chuck 42 to the waveguide section 4420.

Therefore, when the probe tip T4 makes contact with the DUT that is heated by the temperature-controlled chuck 42, the fluid circulating module 462 can be used for stabilizing the thermal condition, so as to block the heat conduction from the temperature-controlled chuck 42 to the waveguide probe 442, thereby reducing variations in the test signals.

Furthermore, in certain cases, the enclosed space E3 of the thermal shielding component TS3 can be connected to another fluid circulating module, and a temperature and a flow rate of the fluid inside the thermal shielding component TS3 can be controlled. For example, the temperature of the cooling air of the waveguide enclosure 460 can be lower than the temperature of the cooling air of the thermal shield component TS3, and the flow rate of the cooling air of the waveguide enclosure 460 can be lower than the flow rate of the cooling air of the thermal shield component TS3, but the present disclosure is not limited thereto.

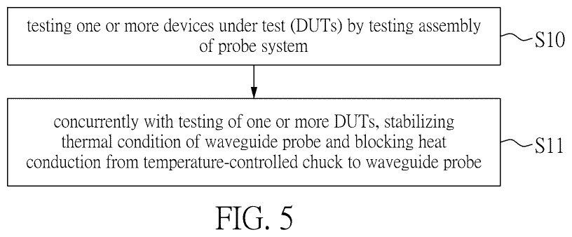

FIG. 5 is a flowchart of a method of utilizing the probe system of the first, second, third and fourth embodiments according to one embodiment of the present disclosure.

Referring to FIG. 5, one embodiment of the present disclosure provides a method that can be performed by using any one of the probe system 1, 2, 3 and 4, the test method includes the following processes:

Step S10: testing one or more devices under test (DUTs) by the testing assembly of the probe system. In step S10, any one of the substrate 18, 28, 38 and 48 including the DUT can be carried by the temperature-controlled chuck 12, 22, 32, or 42, and any one of the testing assembly 14, 24, 34, and 44 can be used to facilitate contact between the probe tip and the DUT. In this embodiment, a testing process can be performed by any one of the testing assembly 14, 24, 34, and 44, so as to test and evaluate a semiconductor device using high-frequency signals. The primary goal of this testing process is to ensure the performance, stability, and reliability of the semiconductor device under high-frequency operating conditions. During high-frequency testing, the testing equipment provides a high-frequency signal (e.g., in the frequency range of hundreds of MHz to GHz) and injects it into the semiconductor device.

The high-frequency signal applied during the test may cover various testing conditions, such as signal amplitude, frequency range, and waveform. The measurement data collected during the test is used to analyze the behavior of the electronic device under high-frequency conditions.

Step S11: concurrently with the testing of the one or more DUTs, stabilizing a thermal condition of the waveguide probe and blocking heat conduction from the temperature-controlled chuck to the waveguide probe. In step S11, the thermal actively-controlled mechanism 16/26/36/46 can be used for stabilizing the thermal condition of the waveguide probe 142/242/342/442 and blocking heat conduction from the temperature-controlled chuck to the waveguide probe 142/242/342/442, and detailed descriptions are provided hereinafter.

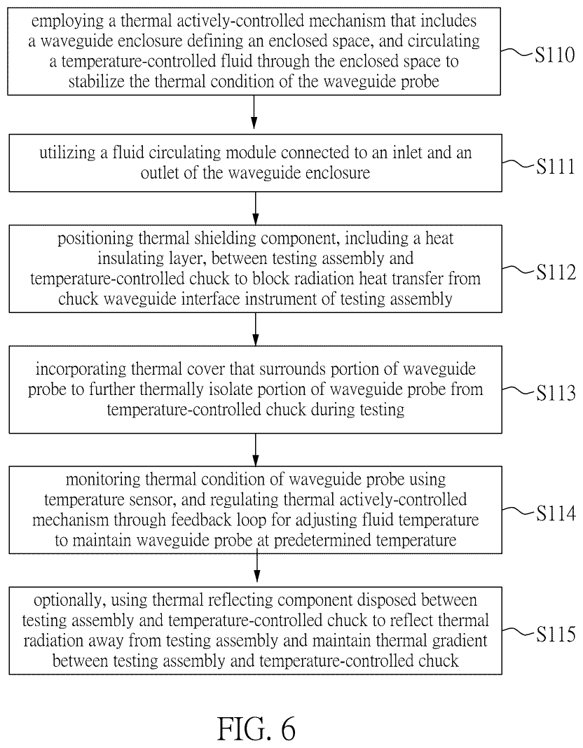

FIG. 6 is a detailed flowchart of step S11. Referring to FIG. 6, step S11 can further include the following steps:

Step S110: employing a thermal actively-controlled mechanism that includes a waveguide enclosure defining an enclosed space, and circulating a temperature-controlled fluid through the enclosed space to stabilize the thermal condition of the waveguide probe.

Step S111: utilizing a fluid circulating module connected to an inlet and an outlet of the waveguide enclosure. For example the fluid circulating module 162/262/362/462 can continuously input a temperature-controlled fluid into the enclosed space E2 through the inlet IN1 and continuously removing fluid from the enclosed space E2 through the outlet OT1, so as to blocking the heat conduction from the temperature-controlled chuck 12/22/32/42 to the waveguide probe 142/242/342/442.

Moreover, step S11 can include at least one of the following steps S112, S113, S114, S115.

Step S112: positioning a thermal shielding component, including a heat insulating layer, between the testing assembly and a temperature-controlled chuck to block radiation heat transfer from the chuck a waveguide interface instrument of the testing assembly. For example, one or more of the thermal shielding components TS1, TS2, TS3 mentioned in the previous embodiments can be utilized in step S112.

Step S113: incorporating a thermal cover that surrounds at least a portion of the waveguide probe to further thermally isolate the portion of the waveguide probe from the temperature-controlled chuck during testing. For example, one or more of the thermal cover TC1 and TC2 mentioned in the previous embodiments can be utilized in step S113.

Step S114: monitoring the thermal condition of the waveguide probe using a temperature sensor, and regulating the thermal actively-controlled mechanism through a feedback loop for adjusting a fluid temperature to maintain the waveguide probe at a predetermined temperature. For example, the temperature sensor can be configured to detect a temperature of the fluid that is continuously removed from the enclosed space E2 through the outlet OT1, and the fluid circulating module 162 can the temperature of the temperature-controlled fluid to be continuously inputted into the enclosed space E2 according to the detected temperature, so as to maintain the waveguide probe at a predetermined temperature for a period of time (e.g., at a stable temperature). The feedback loop can be defined by a control chain formed of the temperature sensor and the thermal actively-controlled mechanism 16/26/26/46.

Step S115: optionally, using a thermal reflecting component disposed between the testing assembly and the temperature-controlled chuck to reflect thermal radiation away from the testing assembly and maintain a thermal gradient between the testing assembly and the temperature-controlled chuck. For example, the thermal reflecting component TR1 mentioned in the previous embodiments can be utilized in step S115.

Furthermore, during the testing of the one or more DUTs, the waveguide interface instrument 140/240/340/440, such as the frequency extender, when present, can be configured to receive test signal from a controller (not represented) at a first frequency and to provide the test signal to probe at a second frequency that is greater than the first frequency. As such, the VNA can extend the operating frequency range of the controller. Examples of the first frequency can include frequencies of at most 10 gigahertz (GHz), at most 20 GHz, at most 30 GHz, at most 40 GHz, at most 50 GHz, at most 60 GHz, at most 70 GHz, and/or at most 80 GHz. Examples of the second frequency include frequencies of at least 50 GHz, at least 60 GHz, at least 70 GHz, at least 80 GHz, at least 90 GHz, at least 100 GHz, at least 200 GHz, at least 300 GHz, at most 1,100 GHz, at most 800 GHz, at most 600 GHz, at most 500 GHz, at most 400 GHz, at most 300 GHz, and/or at most 200 GHz.

As mentioned above, when the probe tip T1/T2/T3/T4 makes contact with the DUT that is heated by the temperature-controlled chuck 12/22/32/42, the fluid circulating module 162/262/362/462 can be used for stabilizing the thermal condition, so as to block the heat conduction from the temperature-controlled chuck 12/22/32/42 to the waveguide probe 142/242/342/442, thereby reducing variations in the test signals.

Furthermore, in the above steps, one or more of the thermal shielding components TS1, TS2, TS3, the thermal cover TC1, TC2, the thermal reflecting component TR1, and the thermal vacuum component TV1 can be utilized, and repeated descriptions are omitted hereinafter.

In certain embodiments, the present disclosure provides a method of testing an unpackaged semiconductor device, including providing the probe system 1/2/3/4, using one or more of the testing assembly 14, 24, 34, and 44 to mechanically and electrically connecting one or more of the substrate 18, 28, 38 and 48. Next, one or more of the substrate 18, 28, 38 and 48 can be tested by transmitting a signal with one or more of the probe system 1, 2, 3 and 4 and via the at least one waveguide probe, such as one or more of the waveguide probe 142, 242, 342 and 442.

In certain embodiments, the present disclosure provides a method of producing a tested semiconductor device. The method includes providing the probe system 1/2/3/4 and an unpackaged semiconductor device formed on the substrate 18/28/38/48, using one or more of the testing assembly 14, 24, 34, and 44 to mechanically and electrically connect at least one contact of one or more of the substrate 18, 28, 38 and 48. Next, one or more of the substrate 18, 28, 38 and 48 can be tested by transmitting a signal with the probe system 1/2/3/4, one or more of the probe system 1, 2, 3 and 4 and via the at least one waveguide probe, such as one or more of the waveguide probe 142, 242, 342 and 442, so as to obtain the tested semiconductor device.

In certain embodiments, the present disclosure provides a tested semiconductor device, which includes an unpackaged semiconductor device having a plurality of pads. The unpackaged semiconductor device can be any one of the substrate 18, 28, 38 and 48, and the plurality of contacts of which are configured to be mechanically and electrically contacted by any one of the testing assembly 14, 24, 34, and 44 after performing the testing process mentioned above.

### Beneficial Effects of the Embodiments

In conclusion, in the probe system, the method of utilizing a probe system, the method of testing the unpackaged semiconductor device, the method of producing the tested semiconductor device and the tested semiconductor device provided by the present disclosure, when the probe tip makes contact with the DUT that is heated by the temperature-controlled chuck, the fluid circulating module can be used for stabilizing the thermal condition, so as to block the heat conduction from the temperature-controlled chuck to the waveguide probe, thereby reducing variations in the test signals.

Moreover, the thermal shielding component can be configured for restricting heat transferring between the testing assembly and the temperature-controlled chuck, shielding a first part of the testing assembly from the temperature-controlled chuck, shielding a second part of the testing assembly from the temperature-controlled chuck, and/or maintaining thermal gradients between the testing assembly and the temperature-controlled chuck when the testing assembly is optionally and detachably disposed above the temperature-controlled chuck.

In addition, the thermal vacuum component forms a vacuum layer significantly reduces heat transfer by conduction and convection between the temperature-controlled chuck and the testing assembly. The thermal reflecting component can be configured for restricting heat transferring between the testing assembly and the temperature-controlled chuck by reflecting thermal radiation away from the testing assembly, shielding at least a part of the testing assembly from thermal radiation emitted by the temperature-controlled chuck, and/or a thermal gradient between the testing assembly 44 and the temperature-controlled chuck by reflecting and managing thermal energy when the testing assembly is optionally and detachably disposed above the temperature-controlled chuck.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe system, comprising:
a platen defining a platen aperture;
a temperature-controlled chuck defining a support surface configured to support a substrate that includes a device under test (DUT), wherein the temperature-controlled chuck is configured to regulate a temperature of the substrate;
a testing assembly optionally and detachably disposed on the platen via a probe mount, including:
a waveguide interface instrument operatively attached to the probe mount; and
a waveguide probe operatively attached to the probe mount via the waveguide interface instrument, and the waveguide probe including a probe tip configured to contact the DUT, wherein at least a portion of the waveguide probe extends through the platen aperture to facilitate contact between the probe tip and the DUT; and
a thermal actively-controlled mechanism configured for stabilizing a thermal condition of the waveguide probe and blocking heat conduction from the temperature-controlled chuck to the waveguide probe.

2. The probe system according to claim 1, wherein the thermal actively-controlled mechanism includes a waveguide enclosure configured for defining an enclosed space, and a portion of the waveguide probe is disposed within the enclosed space.

3. The probe system according to claim 2, wherein the thermal actively-controlled mechanism further includes a fluid circulating module connected to an inlet and an outlet of the waveguide enclosure, and the fluid circulating module is configured for stabilizing the thermal condition by continuously inputting a temperature-controlled fluid into the enclosed space through the inlet and continuously removing fluid from the enclosed space through the outlet, so as to block the heat conduction from the temperature-controlled chuck to the waveguide interface instrument.

4. The probe system according to claim 3, wherein the portion of the waveguide probe includes a waveguide section having a first end and a second end, the first end is operatively attached to a waveguide channel section, and the second end is operatively attached to a frequency extender of the waveguide interface instrument.

5. The probe system according to claim 2, wherein the platen includes:
a thermal shielding component disposed between the testing assembly and the temperature-controlled chuck, wherein the thermal shielding component has a heat insulating layer configured for blocking radiation heat from the temperature-controlled chuck to the waveguide probe; and
a thermal cover surrounding, housing and/or containing the portion of the waveguide probe.

6. The probe system according to claim 5, wherein, when the testing assembly is optionally and detachably disposed above the temperature-controlled chuck, the thermal shielding component is configured for at least one of:
(i) restricting heat transferring between the testing assembly and the temperature-controlled chuck;
(ii) shielding at least a part of the testing assembly from the temperature-controlled chuck; and
(iii) maintaining thermal gradients between the testing assembly and the temperature-controlled chuck.

7. The probe system according to claim 5, further comprising a thermal vacuum component and/or a thermal reflecting component disposed between the testing assembly and the temperature-controlled chuck.

8. The probe system according to claim 7, wherein the thermal reflecting component is configured for at least one of:
(i) restricting heat transferring between the testing assembly and the temperature-controlled chuck by reflecting thermal radiation away from the testing assembly;
(ii) shielding at least a part of the testing assembly from thermal radiation emitted by the temperature-controlled chuck; and
(iii) maintaining a thermal gradient between the testing assembly and the temperature-controlled chuck by reflecting and managing thermal energy when the testing assembly is optionally and detachably disposed above the temperature-controlled chuck.

9. The probe system according to claim 5, wherein the thermal cover covers the platen aperture and has an opening through which the testing assembly penetrates.

10. The probe system according to claim 2, wherein the platen includes a thermal shielding component disposed between the testing assembly and the temperature-controlled chuck, and the thermal shielding component has a heat insulating layer configured for blocking radiation heat from the temperature-controlled chuck to the waveguide probe.

11. The probe system according to claim 10, further comprising a thermal vacuum component and/or a thermal reflecting component disposed between the testing assembly and the temperature-controlled chuck.

12. The probe system according to claim 10, wherein, when the testing assembly is optionally and detachably disposed above the temperature-controlled chuck, the thermal shielding component is configured for at least one of:
(i) restricting heat transferring between the testing assembly and the temperature-controlled chuck;
(ii) shielding at least a part of the testing assembly from the temperature-controlled chuck; and
(iii) maintaining thermal gradients between the testing assembly and the temperature-controlled chuck.

13. A method of utilizing a probe system, the method comprising:
(i) providing the probe system as claimed in claim 1;
(ii) testing one or more devices under test (DUTs) by the testing assembly of the probe system; and
(iii) concurrently with the testing of the one or more DUTs, stabilizing the thermal condition of the waveguide probe and blocking the heat conduction from the temperature-controlled chuck to the waveguide probe, wherein a process of stabilizing the thermal condition and blocking the heat conduction includes:
(a) employing the thermal actively-controlled mechanism that includes a waveguide enclosure defining an enclosed space, and circulating a temperature-controlled fluid through the enclosed space to stabilize the thermal condition of the waveguide probe; and
(b) utilizing a fluid circulating module connected to an inlet and an outlet of the waveguide enclosure, wherein the fluid circulating module continuously inputs the temperature-controlled fluid into the enclosed space through the inlet and continuously removes fluid through the outlet, thereby blocking the heat conduction from the temperature-controlled chuck to the waveguide probe.

14. The method according to claim 13, wherein a process of stabilizing the thermal condition and blocking the heat conduction includes:
(c) positioning a thermal shielding component, including a heat insulating layer, between the testing assembly and a temperature-controlled chuck to block radiation heat transfer from the chuck a waveguide interface instrument of the testing assembly.

15. The method according to claim 13, wherein the process of stabilizing the thermal condition and blocking the heat conduction includes:
(d) incorporating a thermal cover that surrounds at least a portion of the waveguide probe to further thermally isolate the portion of the waveguide probe from the temperature-controlled chuck during testing.

16. The method according to claim 13, wherein the process of stabilizing the thermal condition and blocking the heat conduction includes:
(e) monitoring the thermal condition of the waveguide probe using a temperature sensor, and regulating the thermal actively-controlled mechanism through a feedback loop that adjusts a fluid temperature to maintain the waveguide probe at a predetermined temperature.

17. The method according to claim 13, wherein a process of stabilizing the thermal condition and blocking the heat conduction includes:
(f) optionally, using a thermal reflecting component disposed between the testing assembly and the temperature-controlled chuck to reflect thermal radiation away from the testing assembly and maintain a thermal gradient between the testing assembly and the temperature-controlled chuck.

18. A method of testing an unpackaged semiconductor device being formed on a substrate, the method comprising:
providing the probe system of claim 1;
electrically connecting the testing assembly with the unpackaged semiconductor device by making the probe tip of the testing assembly in contact with the contact of the unpackaged semiconductor device; and
testing the unpackaged semiconductor device by using the testing assembly to transmit a signal between the unpackaged semiconductor device and a tester.

19. A method of producing a tested semiconductor device, the method comprising:
providing the probe system of claim 1;
providing an unpackaged semiconductor device, wherein the unpackaged semiconductor device is formed on a substrate and includes at least one contact;
electrically connecting the testing assembly to the unpackaged semiconductor device by making the probe tip of the testing assembly in contact with the contact of the unpackaged semiconductor device; and
testing the unpackaged semiconductor device by using the testing assembly to transmit a signal between the unpackaged semiconductor device and a tester.

20. A tested semiconductor device, comprising:
an unpackaged semiconductor device having a plurality of contacts configured to be mechanically and electrically contacted by the probe system of claim 1 after performing a testing process.
